(19) United States
(12) Patent Application Publication
(10) Pub. No.: US 2012/0051023 A1
(43) Pub. Date: Mar. 1, 2012

(54) ELECTRONIC APPARATUS

(75) Inventors: Izen Sakuma, Shinagawa-ku (JP); Minoru Enomoto, Higashiyamato-shi (JP)

(73) Assignee: KABUSHIKI KAISHA TOSHIBA, Tokyo (JP)

(21) Appl. No.: 13/218,314

(22) Filed: Aug. 25, 2011

(30) Foreign Application Priority Data
Aug. 25, 2010 (JP) 2010-188837

(51) Int. Cl. H05K 7/00

(52) U.S. Cl. 361/810

(57) ABSTRACT

According to one embodiment, an electronic apparatus includes: a display device including a display screen; a first housing which houses the display device and which includes a first surface having an opening through which the display screen is exposed, and a second surface located on a opposite side to the first surface; a second housing connected to the first housing so that the first housing is rotatable between a first position where the display screen is uncovered and a second position where the display screen is covered; first guard portions attached to the second surface to guard corner portions of the first housing along a circumferential edge of the first housing; and second guard portions which are attached to the second housing to guard corner portions of the second housing along a circumferential edge of the second housing and which abut on the first housing in the second position.

### CROSS REFERENCE TO RELATED APPLICATION(S)

The application is based upon and claims the benefit of priority from Japanese Patent Application No. 2010-188837 filed on Aug. 25, 2010; the entire content of which are incorporated herein by reference.

### FIELD

Embodiments described herein relate generally to an electronic apparatus.

### BACKGROUND

Some electronic apparatuses are provided with housings improved in ruggedness.

There is a demand for a recent electronic apparatus further improved in tolerance to external stress.

### BRIEF DESCRIPTION OF THE DRAWINGS

FIG. 1 is a perspective view showing a state in which a display unit in an electronic apparatus according to a first embodiment is located in a first position.

FIG. 2 is a perspective view showing a state in which the display unit in the electronic apparatus is located in a second position.

FIG. 3 is a sectional view showing the electronic apparatus taken along the line shown in FIG. 2.

FIG. 4 is a view showing an upper wall of a main unit in the electronic apparatus shown in FIG. 1.

FIG. 5 is a view showing an inside of the main unit in the electronic apparatus shown in FIG. 4.

FIG. 6 is a view showing a state in which one of guard portions shown in FIG. 3 is deformed by colliding with an external member.

FIG. 7 is a view showing a state in which one of the guard portions shown in FIG. 3 is damaged by colliding with an external member.

FIG. 8 is a perspective view showing an electronic apparatus according to a second embodiment.

### DETAILED DESCRIPTION OF THE EMBODIMENTS

In general, according to one exemplary embodiment, an electronic apparatus is provided. The electronic apparatus includes: a display device including a display screen; a first housing which houses the display device and which includes a first surface provided with an opening through which the display screen is exposed, and a second surface located so as to be opposite to the first surface; a second housing which is connected to the first housing so that the first housing is rotatable between a first position where the display screen is uncovered and a second position where the display screen is covered; first guard portions which are attached to the second surface to guard corner portions of the first housing along a circumferential edge of the first housing; and second guard portions which are attached to the second housing to guard corner portions of the second housing along a circumferential edge of the second housing and which abut on the first housing in the second position.

Description will be made below with reference to the drawings in which some embodiments are applied to a notebook type personal computer (hereinafter referred to notebook PC) and a television set.

### First Embodiment

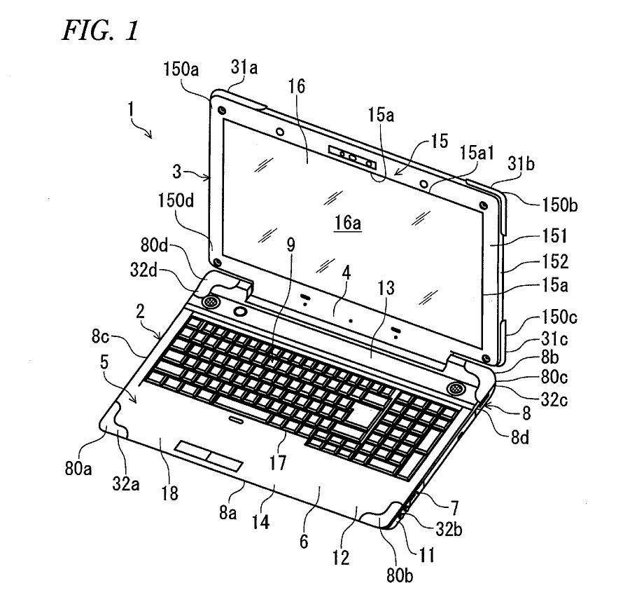

FIGS. 1 to 7 disclose an electronic apparatus 1 according to a first embodiment. For example, the electronic apparatus 1 is a notebook PC. Incidentally, the electronic apparatus can be applied is not limited to the above description. The embodiment can be broadly applied to various electronic apparatuses including a display device such as a television set, a recording/replaying apparatus, a Personal Digital Assistant (PDA), a game machine, etc.

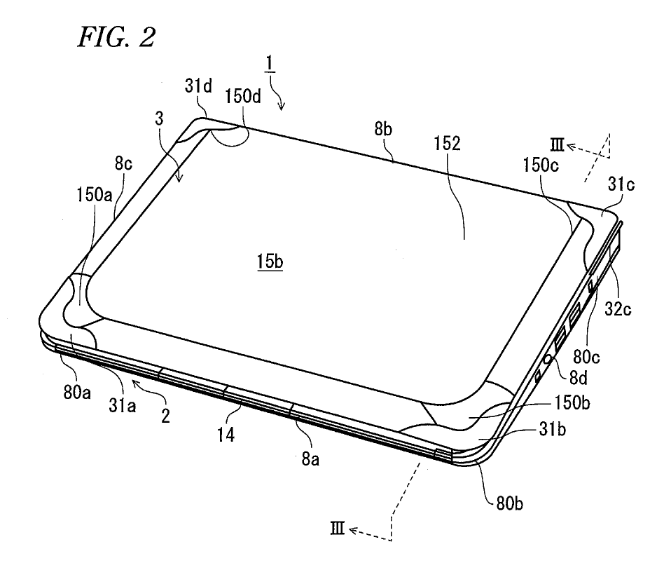

First, the external configuration of the electronic apparatus according to the first embodiment will be described with reference to FIGS. 1 and 2. FIG. 1 is a perspective view showing a state in which a display unit in the electronic apparatus according to the first embodiment is located in a first position. FIG. 2 is a perspective view showing a state in which the display unit in the electronic apparatus according to the first embodiment is located in a second position.

As shown in FIGS. 1 and 2, the electronic apparatus 1 includes a main unit 2, a display unit 3, and a hinge 4. The main unit 2 is an electronic apparatus body in which a main board is mounted. The main unit 2 includes a housing (second housing) 5. The housing 5 includes an upper wall (third surface) 6, a lower wall (fourth surface) 7, a circumferential wall (side surface) 8, and corner portions 80a, 80b, 80c and 80d. The housing 5 is shaped like a flat box.

The lower wall 7 faces a surface of a desk when the electronic apparatus 1 is placed on the desk. The lower wall 7 becomes substantially parallel with the surface of the desk. The upper wall 6 extends substantially in parallel with the lower wall 7 (i.e. substantially horizontally) while a space is formed between the upper wall 6 and the lower wall 7. A keyboard 9 is mounted in the upper wall 6. The circumferential wall 8 stands up with respect to the lower wall 7 and connects a circumferential edge portion of the lower wall 7 and a circumferential edge portion of the upper wall 6 to each other.

The housing 5 includes a base 11, and a cover 12. The base 11 includes the lower wall 7, and part of the circumferential wall 8. The cover 12 includes the upper wall 6, and part of the circumferential wall 8. The cover 12 and the base 11 are combined with each other to thereby form the housing 5.

The housing 5 includes a rear end portion 13, and a front end portion 14. The display unit 3 is connected to the rear end portion 13 so that the display unit 3 can rotate. The front end portion 14 is located so as to be opposite to the rear end portion 13. The circumferential wall 8 includes a front wall 8a, a rear wall 8b, a left side wall 8c, and a right side wall 8d. The front wall 8a extends in a widthwise direction (left-right direction) of the housing 5 in the front end portion 14. The rear wall 8b extends in the widthwise direction of the housing 5 in the rear end portion 13. The left and right side walls 8c and 8d extend in a depthwise direction (front-rear direction) of the housing 5 to connect end portions of the front wall 8a and end portions of the rear wall 8b.

The display unit 3 is connected to the rear end portion 13 of the main unit 2 by the hinge 4 so that the display unit 3 can rotate (can be opened and closed). The display unit 3 can rotate between an open position (first position) where the display unit 3 is lifted up with respect to the main unit 2 as shown in FIG. 1 and a close position where the display unit 3 is pushed down to cover the main unit 2 from above as shown in FIG. 2.

As shown in FIG. 1, the display unit 3 includes a display housing (first housing) 15, and a display panel (display device) 16 received in the display housing 15. The display housing 15 includes a front wall (first surface) 15a, a rear wall (second surface) 15b, a circumferential wall (side surface) 15c, and corner portions 150a, 150b, 150c and 150d. The display housing 15 is shaped like a flat box.

A display screen 16a of the display panel 16 can be exposed to the outside through an opening portion 15a1 provided in the front wall 15a of the display housing 15. The rear wall 15b is located so as to be opposite to the front wall. The rear wall 15b protects a back of the display panel 16.

The display housing 15 includes a mask 151, and a cover 152. The mask 151 includes the front wall 15a, and part of the circumferential wall of the display housing 15. The cover 152 includes the rear wall 15b, and part of the circumferential wall of the display housing 15. The mask 151 and the cover 152 are combined with each other to thereby form the display housing 15.

As shown in FIG. 2, the rear wall 15b includes first elastic members (first guard portions) 31a, 31b, 31c and 31d. The first elastic members 31a, 31b, 31c and 31d are attached to the corner portions 150a, 150b, 150c and 150d respectively correspondingly along a circumferential edge of the display housing 15, i.e. a circumferential edge of the cover 152. Portions of the cover 152 corresponding to the corner portions 150a, 150b, 150c and 150d are guarded with the first elastic members 31a, 31b, 31c and 31d respectively. Incidentally, although an example in which the four corner portions 150a, 150b, 150c and 150d are guarded has been shown here, the embodiment is not limited thereto as long as regions of the cover 152 corresponding to these corner portions can be guarded.

As shown in FIG. 1, the upper wall 6 includes a keyboard mounting portion 17 where the keyboard 9 is mounted, a palm rest 18, and second elastic members (second guard portions or guard portions) 32a, 32b, 32c and 32d. The first elastic members 31a, 31b, 31c and 31d are attached to the corner portions 150a, 150b, 150c and 150d respectively correspondingly along the circumferential edge of the display housing 15, i.e. the circumferential edge of the cover 152. The first elastic members 31a, 31b, 31c and 31d attached to the places corresponding to the corner portions 150a, 150b, 150c and 150d of the display housing 15 are partially located on the outside of the rear wall 15b of the display housing 15 in a thicknesswise direction of the display housing 15.

Portions of the cover 12 corresponding to the corner portions 80a, 80b, 80c and 80d are guarded with the second elastic members 32a, 32b, 32c and 32d respectively. Incidentally, although an example in which the four corner portions 80a, 80b, 80c and 80d are guarded has been shown here, the embodiment is not limited thereto as long as regions of the cover 12 corresponding to these corner portions can be guarded.

As shown in FIG. 1, the palm rest 18 is provided in front of the keyboard mounting portion 17, that is, between the keyboard mounting portion 17 and the front wall 8a. The keyboard mounting portion 17 is dented inside the housing 5 relative to the palm rest 18. In this manner, an upper surface of the keyboard 9 mounted in the keyboard mounting portion 17 is located so as to be substantially equal to or slightly higher than an upper surface of the palm rest 18.

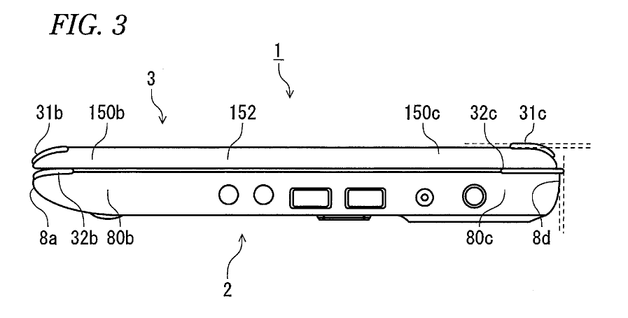

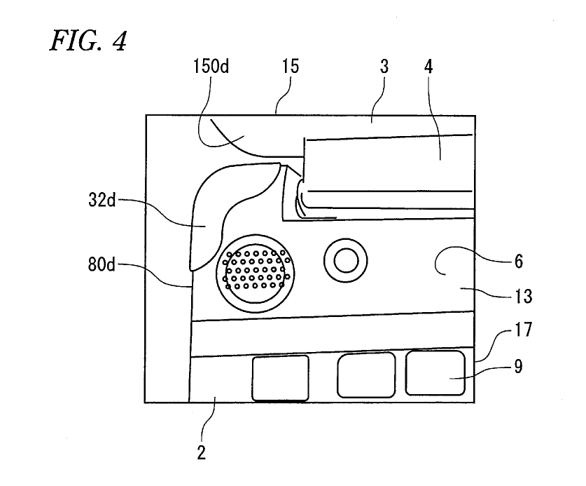

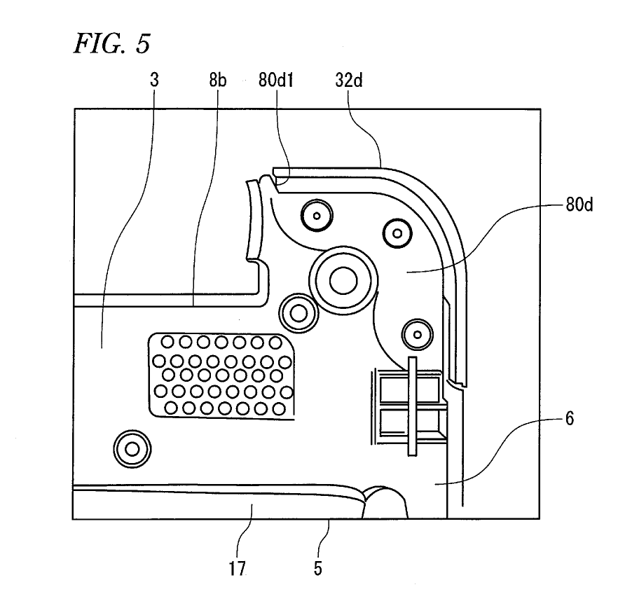

Next, the configuration of the first elastic members 31a, 31b, 31c and 31d and the second elastic members 32a, 32b, 32c and 32d will be described with reference to FIGS. 3 to 7. FIG. 3 is a sectional view of the electronic apparatus taken along the line shown in FIG. 2. FIG. 4 is a view showing the upper wall of the main unit in the electronic apparatus shown in FIG. 1. FIG. 5 is a view showing the inside of the main unit in the electronic apparatus shown in FIG. 4.

Each of the housing 5 and the display housing 15 has a space in which components such as a print circuit board not shown, the display panel 16, etc. are disposed internally. For example, each of the housing 5 and the display housing 15 is made of a resin material. Coating of a conductive film not shown is formed on an inner surface of each of the housing 5 and the display housing 15.

As shown in FIG. 3, the second elastic members 32c and 32d attached to regions of the upper wall 6 corresponding to the corner portions 80c and 80d are partially located on the outside of the circumferential walls of the housing 5 and the display housing 15, respectively. The second elastic members 32c and 32d are partially located on the outside of the first elastic members 31c and 31d, respectively. That is, a maximum outer edge size of the main unit 2 including circumferential edges of the second elastic members 32c and 32d is larger than a maximum outer edge size of the display unit 3 including circumferential edges of the first elastic members 31c and 31d.

As shown in FIG. 3, the housing 5 is thicker than the display housing 15. In addition, the main unit 2 is heavier than the display unit 3 because heavy components such as a cooling module not shown, an HDD not shown, etc. are contained in the inside of the main unit 2. In addition, a rear side thickness, i.e. a hinge 4 side thickness of each of the housing 5 and the display housing 15 is designed to be larger than a front side thickness, i.e. a palm rest side thickness thereof in order to make the electronic apparatus 1 apparently thin in the position where the display unit 3 is closed, i.e. in the second position. Since relatively large ones of the components received in the housing 5 are placed near to the hinge 4 side and the weight of the hinge 4 made of metal is added, the gravitational center of the electronic apparatus 1 comes near to the rear side.

With such a configuration, when, for example, the electronic apparatus 1 according to the embodiment is dropped down, there is a high possibility that the electronic apparatus 1 will collide with the ground at the corner portion 80c or 80b, particularly there is a high possibility that contact of the electronic apparatus 1 with the ground will start at the second elastic member 32b or 32c. In this case, in the electronic apparatus 1 according to this embodiment, stress can be absorbed by elasticity of the second elastic member 32b or 32c to thereby relax shock transmitted to the electronic apparatus 1.

As shown in FIGS. 4 and 5, the first elastic members 31 (31a, 31b, 31c and 31d) and the second elastic members 32 (32a, 32b, 32c and 32d) are disposed in four places corresponding to the four corners of the housing 5 and in four places corresponding to the four corners of the display housing 15, respectively. Each of the first elastic members 31 and the second elastic members 32 is shaped like an “L” figure, a “U” figure, a “<” figure, a semicircle, etc., so that the first elastic members 31 and the second elastic members 32 protect the four corners of the housing 5 and the four corners of the display housing 15, respectively.

As shown in FIGS. 3 and 4, the second elastic members 32a, 32b, 32c and 32d are composed of resin materials 32a1, 32b1, 32c1 and 32d1 to be bonded to the housing 5, and elastic materials 32a2, 32b2, 32c2 and 32d2, for example, made of rubber and bonded to these resin materials 32a1, 32b1, 32c1 and 32d1 respectively.

The second elastic members 32a, 32b, 32c and 32d serve as cushioning members. Specifically, the second elastic members 32a, 32b, 32c and 32d are designed to hit against (abut on) the main unit 2 when the display unit 3 rotates to a position where the display unit 3 is put on top of the main unit 2, that is, when the display unit 3 rotates so that the mask 151 of the display housing 15 faces the main unit 2.

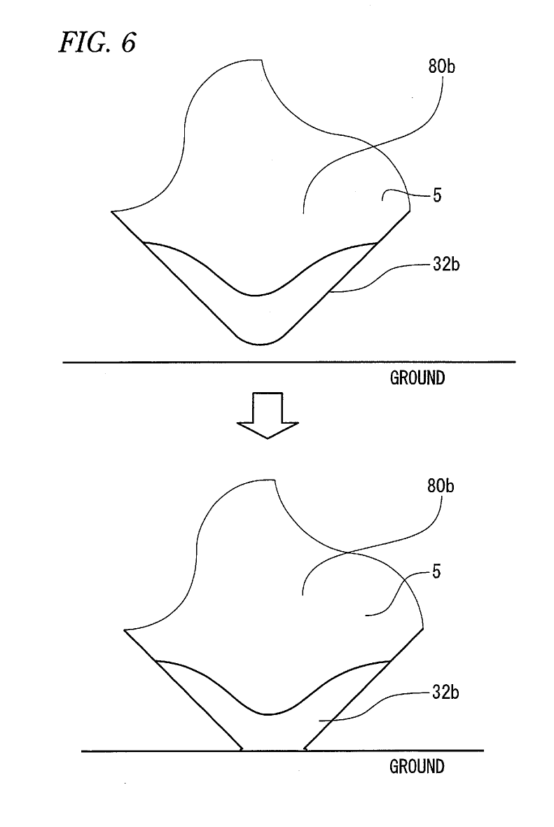

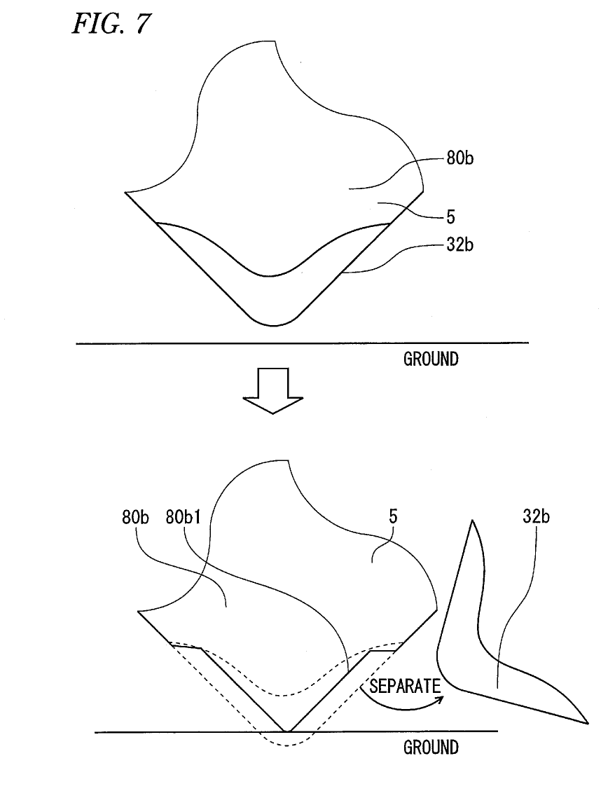

Next, effect of the first elastic members 31a, 31b, 31c and 31d and the second elastic members 32a, 32b, 32c and 32d will be described below with reference to FIGS. 6 and 7. FIGS. 6 and 7 are views showing a state in which the electronic apparatus 1 collides with the ground at one of the corner portions 80a, 80b, 80c and 80d or at one of the corner portions 150a, 150b, 150c and 150d when the electronic apparatus 1 is dropped down. FIG. 6 is a view showing a state in which one of the guard portions shown in FIG. 3 is deformed by colliding with an external member. FIG. 7 is a view showing a state in which one of the guard portions shown in FIG. 3 is damaged by colliding with an external member. Although the state in the vicinity of the corner portion 80b on which the second elastic member 32b is provided has been described here by way of example, functions of the other second elastic members and the first elastic members are the same as described above.

As described above, when the electronic apparatus 1 according to the embodiment is dropped down, there is a high possibility that the electronic apparatus 1 will collide with the ground at one of the corner portions 80a, 80b, 80c and 80d (particularly at one of the corner portions 80c and 80d) and there is a high possibility that contact of the electronic apparatus 1 with the ground will start at one of the second elastic members 32c and 32d.

In this case, as shown in FIG. 6, in the electronic apparatus 1 according to the first embodiment, the elasticity of the first and second elastic members is larger than the elasticity of a material forming the housing 5. For this reason, stress can be absorbed by the elasticity of the second elastic members to thereby relax shock transmitted to the electronic apparatus 1.

As shown in FIG. 5, in the electronic apparatus 1 according to this embodiment, the display housing 15, the body housing 5 and the first and second elastic members are formed as separate components. Opening portions 80a1, 80b1, 80c1 and 80d1 and corner portions 150a1, 150b1, 150c1 and 150d1 are provided in the corner portions 80a, 80b, 80c and 80d and the corner portions 150a, 150b, 150c and 150d, respectively. The first elastic members 31a, 31b, 31c and 31d and the second elastic members 32a, 32b, 32c and 32d are provided so that the opening portions 80a1, 80b1, 80c1 and 80d1 and the corner portions 150a1, 150b1, 150c1 and 150d1 are guarded with the first elastic members 31a, 31b, 31c and 31d and the second elastic members 32a, 32b, 32c and 32d, respectively. Although FIG. 5 shows a region near the corner portion 80d for the sake of simplifying description, configurations of the other corner portions are the same as described above.

With such a configuration, in the electric apparatus 1 according to this embodiment, when intense shock is given in the vicinity of one of the corner portions, not only can stress be absorbed by the elasticity of the first and second elastic members but also stress can be released without stress transmitted to the body housing and the display housing because the first and second elastic members are separated from these housings.

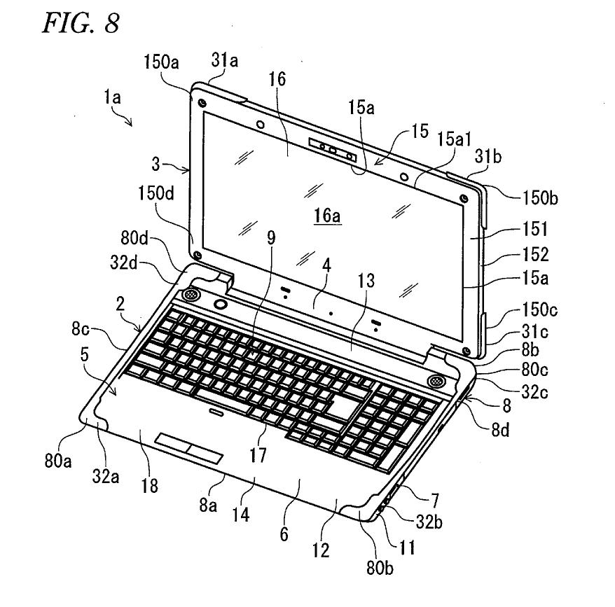

Successively, a second embodiment of an electronic apparatus will be described with reference to FIG. 8. A portable computer 1a which is an example of the electronic apparatus according to the second embodiment is the same as in the first embodiment except that shapes of second elastic members 32a, 32b, 32c and 32d are different from those in the first embodiment. Therefore, different parts will be mainly described while the other common parts will be referred to by the same numerals and description thereof will be omitted. The portable computer 1a according to the second embodiment has an external appearance substantially the same as that shown in FIG. 1.

As shown in FIG. 8, the second elastic members 32a, 32b, 32c and 32d in the second embodiment are connected consecutively. That is, the second elastic members 32a, 32b, 32c and 32d have a frame-like or loop-like form surrounding an outer circumference of the upper wall 6 of the housing 5. With such a configuration, bonding strength between the second elastic members 32a, 32b, 32c and 32d and the housing 5 can be improved and improvement in assembling workability and wide-range tolerance to external stress can be kept.

The electronic apparatus is not limited to the portable computer 1a shown in each of the embodiments. It is a matter of course that the electronic apparatus can be applied to any other electronic apparatus such as a cell phone. The electronic apparatus is not limited to the aforementioned embodiments per se and constituent members may be modified for embodying the electronic apparatus without departing from the gist of the invention in a practical stage. While certain embodiment has been described, the exemplary embodiment has been presented by way of example only, and is not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a display device comprising a display screen;
a first housing configured to house the display device, the first housing comprising a first surface comprising an opening through which the display screen is exposed, and a second surface opposite the first surface;
a second housing rotatably connected to the first housing, the first housing being rotatable between a first position where the display screen is uncovered and a second position where the display screen is covered;
a plurality of first guard portions attached to the second surface, the first guard portions configured to guard corner portions of the first housing along a circumferential edge of the first housing; and
a plurality of second guard portions attached to the second housing, the second guard portions configured to guard corner portions of the second housing along a circumferential edge of the second housing,
wherein the second guard portions abut the first housing when the first housing is in the second position.

2. The apparatus of claim 1, wherein:
the first housing further comprises end portions comprising side surfaces;
the second housing further comprises end portions comprising side surfaces; and
the second guard portions are partially disposed outside of the side surfaces of the first housing and the side surfaces of the second housing when the first housing is in the second position.

3. The apparatus of claim 2, wherein:
the second housing comprises a third surface comprising a keyboard, and a fourth surface opposite the third surface; and
the second guard portions are on the third surface and configured to guard the corner portions of the second housing along the circumference edge of the second housing.

4. The apparatus of claim 3, wherein each of the second guard portions comprises a resin portion attached to the second housing, and an elastic portion bonded to the resin portion and abutting the first housing when the first housing is in the second position.

5. The apparatus of claim 2, wherein each of the second guard portions comprises a portion outside of a corresponding first guard portion, when the first housing is in the second position.

6. The apparatus of claim 3, wherein each of the first guard portions comprises a portion outside of the first surface.

7. An electronic apparatus comprising:
a display device including a display screen;
a first housing configured to house the display device, the first housing comprising a first surface comprising an opening through which the display screen is exposed, and a second surface opposite the first surface;
a second housing rotatably connected to the first housing, the first housing being rotatable between a first position where the display screen is uncovered and a second position where the display screen is covered;
a plurality of guard portions attached to the second housing and configured to guard corner portions of the second housing along a circumferential edge of the second housing, wherein the guard portions abut the first housing when the first housing is in the second position.

8. The apparatus of claim 7, wherein:
the first housing further comprises end portions comprising side surfaces;
the second housing further comprises end portions comprising side surfaces; and
the guard portions are partially outside of the side surfaces the first housing and the side surfaces of the second housing, when the first housing is in the second position.

9. The apparatus of claim 8, wherein:
the second housing comprises a third surface comprising a keyboard, and a fourth surface opposite the third surface; and
the guard portions are on the third surface and configured to guard the corner portions of the second housing along the circumference edge of the second housing.

10. The apparatus of claim 9, wherein each of the guard portions comprises a resin portion attached to the second housing, and an elastic portion bonded to the resin portion and abutting the first housing when the first housing is in the second position.
